(19) United States
(12) Patent Application Publication
(10) Pub. No.: US 2026/0372163 A1
(43) Pub. Date: Nov. 19, 2026

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventors: Yonghyun KIM, Suwon-si (KR); Wonil SEO, Suwon-si (KR); Sanghyeon LEE, Suwon-si (KR); Taejun JEON, Suwon-si (KR)

(73) Assignee: Samsung Electronics Co., Ltd., Suwon-si (KR)

(21) Appl. No.: 19/357,639

(22) Filed: Oct. 14, 2025

(30) Foreign Application Priority Data
Jan. 22, 2025 (KR) 10-2025-0009305

(51) Int. Cl. H10W 72/00; H10W 72/20; H10W 72/49; H10W 74/10; H10W 90/00; H10W 90/20; H10W 90/24; H10W 90/26

(52) U.S. Cl. CPC H10W 72/834; H10W 72/244; H10W 72/283; H10W 72/49; H10W 74/117; H10W 74/121; H10W 74/141; H10W 90/24; H10W 90/26; H10W 90/291; H10W 90/722; H10W 90/724

(57) ABSTRACT

A semiconductor package includes a substrate including a bonding pad, vertically stacked chip modules having a first surface and a second surface opposite to the first surface, and a mold covering the chip modules. Each of the chip modules includes a plurality of semiconductor chips each having at least one side surface including a connection pattern, an interconnection pattern contacting an end of the connection pattern of each of the plurality of semiconductor chips, the interconnection pattern including a first terminal portion on the first surface and a second terminal portion on the second surface, and an encapsulant. At least one of first terminal portion and the second terminal portion is electrically connected to a vertically adjacent one among the bonding pad, the first terminal portion of a vertically adjacent one of the chip modules, and the second terminal portion of the vertically adjacent one of the chip modules.

### CROSS-REFERENCE TO RELATED APPLICATION

This application claims priority under 35 U.S.C. §119 to Korean Patent Application No. 10-2025-0009305, filed on Jan. 22, 2025, in the Korean Intellectual Property Office, the disclosure of which is incorporated by reference herein in its entirety.

### BACKGROUND

The present disclosure relates to a semiconductor package and a method of manufacturing the same.

With the development of the electronics industry, demand for implementation of high performance and miniaturization of electronic components has been increasing. A semiconductor package including a plurality of wire-bonded semiconductor chips has limitations in implementing a fine pitch of a connection pad and reducing a thickness of a semiconductor package due to a shape of a bonding wire, for example, a ball size, a height of a wire loop, or the like.

### SUMMARY

One or more example embodiments of the present disclosure may provide a high-performance and reduced-size semiconductor package and a method of manufacturing the same.

According to an aspect of the disclosure, a semiconductor package may include: a substrate including a bonding pad; chip modules, each of the chip modules including a first surface and a second surface opposite to the first surface, the chip modules beign stacked in a vertical direction, one of the first surface or the second surface facing the substrate; and a mold covering the chip modules, wherein each of the chip modules includes: a plurality of semiconductor chips each including a connection pattern, the connection pattern including an end aligned with at least one side surface of each of the plurality of semiconductor chips; an interconnection pattern contacting the end of the connection pattern of each of the plurality of semiconductor chips, the interconnection pattern including: a first terminal portion on the first surface; and a second terminal portion on the second surface; and an encapsulant covering at least a portion of each of the plurality of semiconductor chips and covering the interconnection pattern, and wherein at least one of the first terminal portion or the second terminal portion is electrically connected to a vertically adjacent one among: the bonding pad, the first terminal portion of a vertically adjacent one of the chip modules, and the second terminal portion of the vertically adjacent one of the chip modules.

According to an aspect of the disclosure, a semiconductor package may include: a substrate including a bonding pad; chip modules, each of the chip modules including a first surface and a second surface opposite to the first surface, the chip modules being stacked in a vertical direction, such that the first surface or second surface faces the substrate; and a mold covering the chip modules, wherein each of the chip modules includes: a plurality of semiconductor chips each including a connection pattern; an interconnection pattern connecting the connection patterns of the plurality of semiconductor chips to each other, the interconnection pattern including a first terminal portion on the first surface and a second terminal portion on the second surface; and an encapsulant covering at least a portion of each of the plurality of semiconductor chips and covering the interconnection pattern, wherein at least one of first terminal portion and the second terminal portion is electrically connected to a vertically adjacent one among: the bonding pad, the first terminal portion of a vertically adjacent one of the chip modules, and the second terminal portion of the vertically adjacent one of the chip modules.

According to an aspect of the disclosure, a semiconductor package may include: a substrate; chip modules, each of the chip modules including a first surface and a second surface opposite to the first surface, the chip modules being stacked such that the first surface or the second surface faces the substrate; and a mold covering the chip modules, wherein each of the chip modules includes: a plurality of semiconductor chips each including a connection pattern; an interconnection pattern extending in a stacking direction of the plurality of semiconductor chips and connected to the connection pattern of each of the plurality of semiconductor chips, the interconnection pattern including a first terminal portion on the first surface and a second terminal portion on the second surface; and an encapsulant covering at least a portion of each of the plurality of semiconductor chips and covering the interconnection pattern, and wherein each of the chip modules is electrically connected to a vertically adjacent one among the chip modules, through at least one of the first terminal portion and the second terminal portion.

According to another aspect of the disclosure, a method of manufacturing semiconductor package may include forming chip stacks on a carrier, each of the chip stacks including semiconductor chips stacked such that side surfaces of each of the semiconductor chips are aligned in a vertical direction, forming an interconnection pattern on at least one side surface of each of the chip stacks, the interconnection pattern including a first terminal portion and a second terminal portion, the interconnection pattern contacting ends of connection patterns aligned on the side surfaces of the semiconductor chips, forming an encapsulation material layer covering the chip stacks, at least a portion of the first terminal portion or the second terminal portion being exposed, separating chip modules including the chip stacks from each other, disposing one of the chip modules on a strip substrate, a first surface on which the first terminal portion is disposed or a second surface on which the second terminal portion is disposed being disposed to face toward the strip substrate, stacking additional ones of the chip modules on the strip substrate, each of the chip modules being electrically connected to at least one other of the chip modules adjacent thereto in a stacking direction through at least one of the first terminal portion or the second terminal portion, and forming a molding material layer covering side surfaces of the chip modules.

According to another aspect of the disclosure, the method may include forming an attachment member and a conductive member on the first surface or the second surface of each of the chip modules.

According to another aspect of the disclosure, the conductive member may electrically connect vertically adjacent ones among: a bonding pad, the first terminal portion, or the second terminal portion, to each other.

According to another aspect of the disclosure, the molding material layer may cover the first terminal portion or the second terminal portion exposed to an upper surface of an uppermost one of the chip modules.

### BRIEF DESCRIPTION OF DRAWINGS

The above and other aspects, features, and advantages of the present disclosure will be more apparent from the following detailed description, taken in conjunction with the accompanying drawings, in which:

FIG. 1A is a cross-sectional view of a semiconductor package according to an example embodiment, and FIG. 1B is a longitudinal cross-sectional view of a semiconductor package according to an example embodiment;

FIG. 2 is a longitudinal cross-sectional view of a semiconductor package according to an example embodiment;

FIG. 3 is a longitudinal cross-sectional view of a semiconductor package according to an example embodiment;

FIG. 4 is a longitudinal cross-sectional view of a semiconductor package according to an example embodiment;

FIG. 5 is a longitudinal cross-sectional view of a semiconductor package according to an example embodiment;

FIG. 6 is a longitudinal cross-sectional view of a semiconductor package according to an example embodiment;

FIG. 7 is a longitudinal cross-sectional view of a semiconductor package according to an example embodiment;

FIGS. 8A, 8B, 8C and 8D are diagrams illustrating a process of manufacturing a chip module according to an example embodiment; and

FIGS. 9A, 9B, 9C and 9D are diagrams illustrating a process of manufacturing a semiconductor package according to an example embodiment.

### DETAILED DESCRIPTION

Hereinafter, example embodiments will be described in detail with reference to the accompanying drawings. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

As used herein, expressions such as “at least one of,” when preceding a list of elements, modify the entire list of elements and do not modify the individual elements of the list. For example, the expression, "at least one of a, b, or c," should be understood as including only a, only b, only c, both a and b, both a and c, both b and c, or all of a, b, and c.

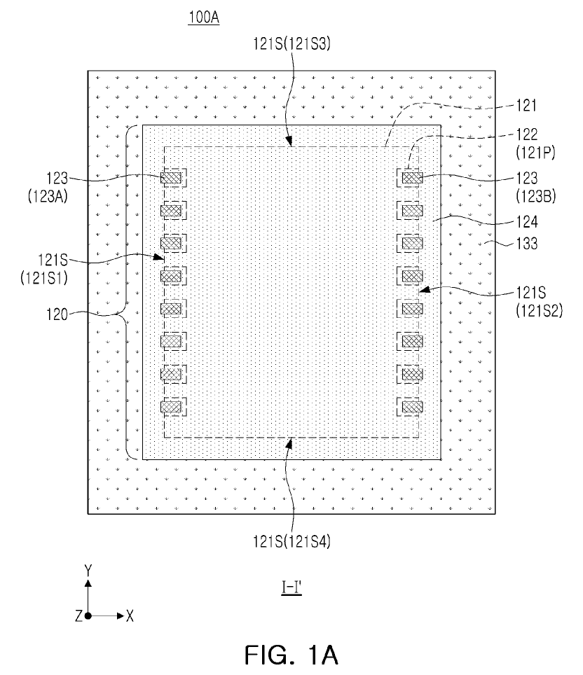

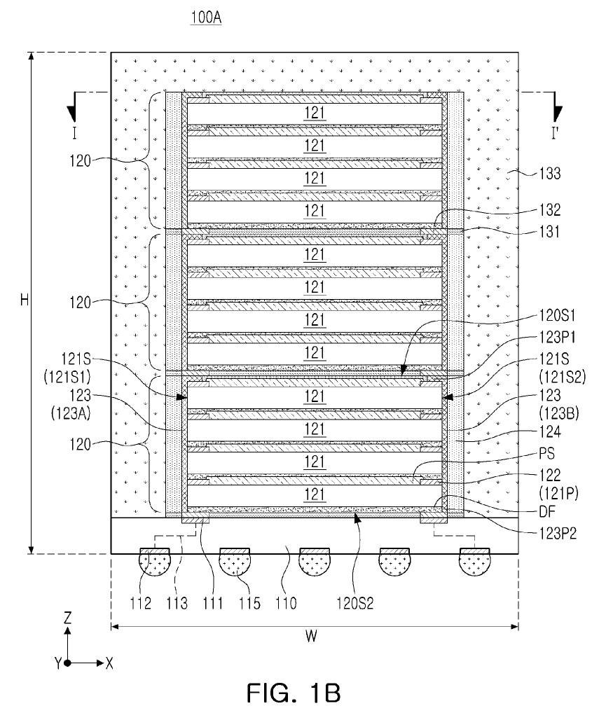

FIG. 1A is a cross-sectional view of a semiconductor package 100A according to an example embodiment, and FIG. 1B is a longitudinal cross-sectional view of a semiconductor package 100A according to an example embodiment. FIG. 1A is a cross-section taken along line I-I’ of FIG. 1B.

Referring to FIGS. 1A and 1B, the semiconductor package 100A according to an example embodiment may include a substrate 110 and chip modules 120. In one or more example embodiments, the semiconductor package 100A may further include an attachment member 131, a conductive member 132, and/or a mold 133. The chip modules 120 according to an example embodiment may implement an electrical connection between the stacked semiconductor chips 121 in a simplified structure. The chip modules 120 may electrically connect a plurality of semiconductor chips 121 stacked in a vertical direction (Z-direction) without a structure such as a bonding wire, a solder bump, a through-via (for example, a through-silicon via (TSV)), or the like. Accordingly, the semiconductor package may overcome structural and spatial limitations that may arise when the bonding wire and the solder bump are used, and may avoid high-level processes such as a through-via formation process and an ultra-high stacking process. As a result, the yield of the high-performance and reduced-size semiconductor package may increase, and manufacturing costs may be reduced.

The substrate 110 may be a substrate for a semiconductor package including a printed circuit board (PCB), a ceramic substrate, a glass substrate, a tape connection substrate, or the like. For example, the substrate 110 may be a double-sided PCB or a multilayer PCB.

The substrate 110 may include bonding pads 111, bump pads 112, and a connection 113 electrically connecting one of the bonding pads 111 and one of the bump pads 112 to each other. The bonding pads 111 may be disposed on an upper surface of the substrate 110, and the bump pads 112 may be disposed on a lower surface of the substrate 110. The bonding pads 111 and the bump pads 112 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn).

Connection bumps 115 may be disposed on lower portions of the bump pads 112. The connection bumps 115 may be electrically connected to the chip modules 120 through the connection 113. The connection bumps 115 may include, for example, tin (Sn) or an alloy (for example, Sn-Ag-Cu) including tin (Sn). The connection bumps 115 may be electrically connected to an external device such as a module substrate, a system board, or the like.

The chip modules 120 may be stacked on the substrate 110 in the vertical direction (Z-direction). The chip modules 120 may have a first surface 120S1 and a second surface 120S2 opposite to each other, and the first surface 120S1 or the second surface 120S2 may be stacked to be oriented toward the substrate 110. The chip modules 120 may implement a connection between the plurality of semiconductor chips 121 and a connection between the chip modules 120, and a connection with the substrate 110 in a simplified structure. Accordingly, the semiconductor package 100A according to an example embodiment may have a significantly reduced width W in a bonding direction (for example, an X-direction) and a significantly reduced height H in a stacking direction (Z-direction), as compared to a package in which the same number of semiconductor chips 121 are stacked. For example, as compared to a case in which the semiconductor chips 121 are wire-bonded to the bonding pad 111, the width W of the semiconductor package 100A may be reduced by about 50% or more. The chip modules 120 may include a plurality of semiconductor chips 121, an interconnection pattern 123, and an encapsulant 124. Hereinafter, components of the chip modules 120 will be described in more detail.

The plurality of semiconductor chips 121 may include a non-volatile memory chip such as a flash memory, a phase-change random access memory (PRAM), a magnetoresistive random access memory (MRAM), a ferroelectric random access memory (FeRAM), or a resistive random access memory (RRAM), and/or a volatile memory chip such as a dynamic random access memory (DRAM) or a static random access memory (SRAM). The plurality of semiconductor chips 121 may include the same type of semiconductor chips, but one or more example embodiments are not limited thereto. Depending on an example embodiment, the plurality of semiconductor chips 121 may include different types of semiconductor chips.

The plurality of semiconductor chips 121 may be stacked in the vertical direction (Z-direction) in the chip module 120. The plurality of semiconductor chips 121 may be stacked such that side surfaces 121S are aligned in the vertical direction (Z-direction). For example, a connection pad 121P of each of the plurality of semiconductor chips 121 may overlap the other semiconductor chips 121 adjacent thereto in the vertical direction (Z-direction). The number of the stacked plurality of semiconductor chips 121 may be greater than the number (4), which are illustrated in the drawings according to an example embodiment.

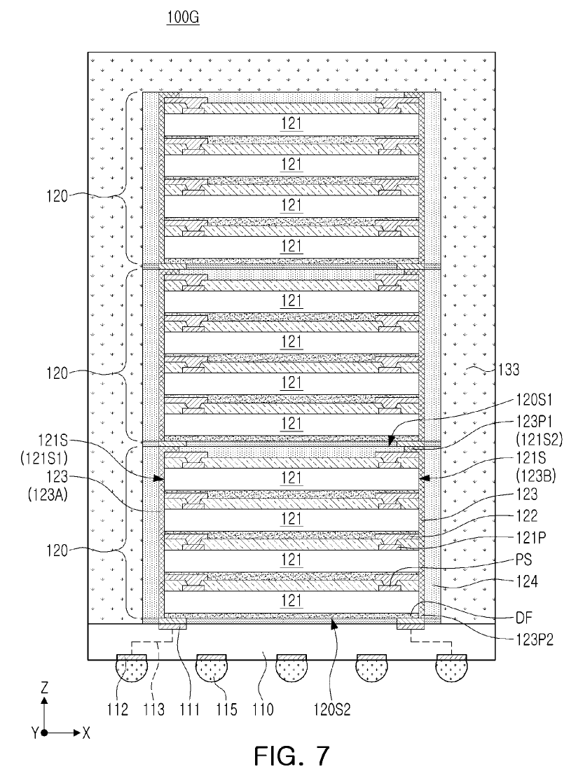

The plurality of semiconductor chips 121 may include a connection pattern 122. The plurality of semiconductor chips 121 may be stacked such that a surface on which the connection pattern 122 is disposed is oriented in the same direction. The connection pattern 122 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The connection pattern 122 may be disposed to be adjacent to at least one side surface 121S of each of the plurality of semiconductor chips 121. The connection pattern 122 may have an end aligned with the one side surface 121S of the semiconductor chip 121. The end of the connection pattern 122 may be coplanar with the one side surface 121S of a corresponding semiconductor chip 121. The connection pattern 122 may be a connection pad 121P of a bare chip, but one or more example embodiments are not limited thereto. In one or more example embodiments, the connection pattern 122 may be a pattern extending the connection pad 121P to the one side surface 121S of the semiconductor chip 121 (see e.g., the example embodiment of FIG. 7).

The connection patterns 122 may be arranged along at least one side surface 121S of the semiconductor chip 121. For example, the semiconductor chip 121 having a first side surface 121S1, a second side surface 121S2, a third side surface 121S3, and a fourth side surface 121S4 may include first connection patterns 122 adjacent to the first side surface 121S1, and second connection patterns 122 adjacent to the second side surface 121S2. In this case, the interconnection pattern 123 may include a first interconnection pattern 123A connecting the first connection patterns 122 to each other on the first side surface 121S1, and a second interconnection pattern 123B connecting the second connection patterns 122 to each other on the second side surface 121S2.

The plurality of semiconductor chips 121 may further include a passivation layer PS covering at least a portion of each of the connection patterns 122. The passivation layer PS may expose at least a portion of each of the connection patterns 122. The passivation layer PS may include a single-layer or multi-layer insulating film. For example, the passivation layer PS may include an oxide film and/or a nitride film. In one or more example embodiments, the passivation layer PS may include photosensitive polyimide (PSPI).

The plurality of semiconductor chips 121 may be attached to each other using adhesive layers DF. The adhesive layers DF may be disposed on one surface of each of the plurality of semiconductor chips 121 opposite to the connection pattern 122. The adhesive layer DF may be formed using an adhesive film, an adhesive paste, or the like. The adhesive layer DF may be a die attach film (DAF), but one or more example embodiments are not limited thereto. At least one adhesive layer DF (for example, an adhesive layer most adjacent to a second terminal portion 123P2) in the chip module 120 may define the second surface 120S2 of the chip module 120.

The interconnection pattern 123 may connect the connection patterns 122 of the plurality of semiconductor chips 121 to each other. The interconnection pattern 123 may extend in the stacking direction (Z-direction) of the semiconductor chips 121 along the one side surfaces 121S of the plurality of semiconductor chips 121. The interconnection pattern 123 may connect the connection patterns 122, adjacent to the one side surfaces 121S of the plurality of semiconductor chips 121. The interconnection pattern 123 may be in contact with ends of the connection patterns 122 aligned on the one side surfaces 121S of the semiconductor chips 121. The interconnection pattern 123 may be formed using, for example, conductive ink including a metal such as aluminum (Al), silver (Ag), or the like.

The interconnection pattern 123 may provide a terminal portion for electrical connection to the plurality of semiconductor chips 121. The interconnection pattern 123 may include a first terminal portion 123P1 on the first surface 120S1 and a second terminal portion 123P2 on the second surface 120S2. The first terminal portion 123P1 and the second terminal portion 123P2 may be positioned to be opposite to each other in the stacking direction (Z-direction). The first terminal portion 123P1 may be exposed to the first surface 120S1 of the chip module 120, and the second terminal portion 123P2 may be exposed to the second surface 120S2 of the chip module 120. A portion of the first terminal portion 123P1 may be coplanar with the first surface 120S1, and a portion of the second terminal portion 123P2 may be coplanar with the second surface 120S2. The interconnection pattern 123 may be in close contact with the side surfaces 121S of the plurality of semiconductor chips 121, thereby minimizing a connection distance between the plurality of semiconductor chips 121. In addition, the interconnection pattern 123 may be exposed to both surfaces of the chip module 120, and thus a connection between the chip modules 120 stacked in the vertical direction (Z-direction) and the substrate 110 may be simplified.

The encapsulant 124 may cover at least a portion of each of the plurality of semiconductor chips 121 and the interconnection pattern 123. The encapsulant 124 may be formed to surround the side surfaces 121S of the plurality of semiconductor chips 121. The encapsulant 124 may include a thermosetting resin such as an epoxy resin, a thermoplastic resin such as polyimide, or a resin in which the thermosetting resin or the thermoplastic resin is impregnated with an inorganic filler, for example, a prepreg, an Ajinomoto build-up film (ABF), flame retardant (FR)-4, bismaleimide triazine (BT), or an epoxy molding compound (EMC). The encapsulant 124 may be formed using a transfer molding process and/or a compression molding process. The encapsulant 124 may expose at least a portion of each of the first terminal portion 123P1 and the second terminal portion 123P2. The encapsulant 124 may define the first surface 120S1 of the chip module 120, on a semiconductor chip most adjacent to the first terminal portion 123P1, among the plurality of semiconductor chips 121.

In an example embodiment, the chip modules 120 may be electrically connected to at least a vertically adjacent one chip module 120 through at least one first terminal portion 123P1 and at least one second terminal portion 123P2. The at least one of first terminal portion 123P1 or the one second terminal portion 123P2 may be electrically connected to a vertically adjacent one among the bonding pad 111, the first terminal portion 123P1, and the second terminal portion 123P2, adjacent thereto in the vertical direction (Z-direction). According to an example embodiment, an electrical connection between the first terminal portion 123P1 and the second terminal portion 123P2 may be formed by the attachment member 131 and the conductive member 132.

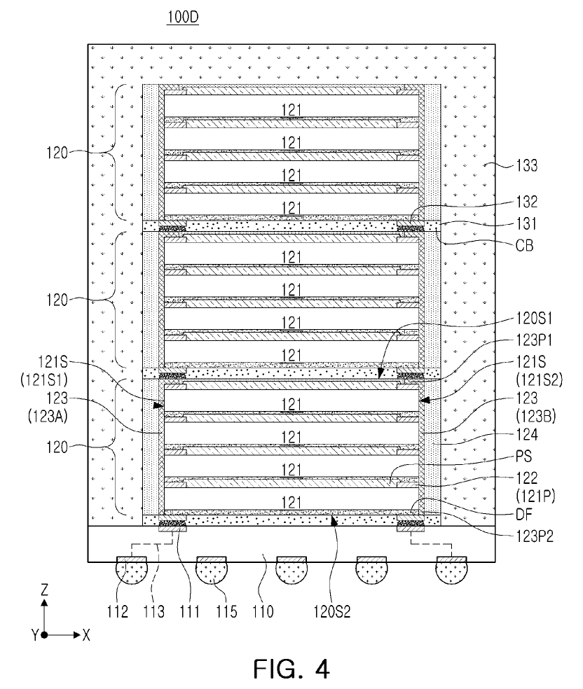

The attachment members 131 may be disposed between the chip modules 120 and between the substrate 110 and one of the chip modules 120. The attachment members 131 may attach and fix the chip modules 120 and electrically insulate the conductive members 132 from each other. The attachment members 131 may be formed using an insulating material. The attachment members 131 may comprise a polymer resin layer, an oxide film, a nitride film, or the like (silicon oxide or silicon nitride). For example, the attachment members 131 may be non-conductive films (NCF), but one or more example embodiments are not limited thereto. In one or more example embodiments, the attachment member 131 may include an anisotropic conductive film (ACF) (for example, the example embodiment of FIG. 4).

The conductive members 132 may be disposed in the attachment members 131. The conductive member 132 may electrically connect vertically adjacent ones among the bonding pad 111, the first terminal portion 123P1, or the second terminal portion 123P2, adjacent to each other in the vertical direction (Z-direction) . The conductive members 132 may be in direct contact with a corresponding first terminal portion 123P1 or second terminal portion 123P2, and may protrude onto the first surface 120S1 or the second surface 120S2 of the chip module 120. The conductive members 132 may be in contact with two components, among the bonding pad 111, the first terminal portion 123P1, and the second terminal portion 123P2, corresponding to each other in the vertical direction (Z-direction). In one or more example embodiments, the conductive members 132 may be in contact with only one of the two components corresponding to each other in the vertical direction (Z-direction) (for example, the example embodiment of FIG. 4). The conductive members 132 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn).

The mold 133 may cover the chip modules 120 on the substrate 110. The mold 133 may surround side surfaces of the chip modules 120. The mold 133 may cover an upper surface of an uppermost chip module 120. For example, the mold 133 may cover a first terminal portion 123P1 of the uppermost chip module 120. For example, the mold 133 may include a prepreg, an ABF, FR-4, BT, or an EMC.

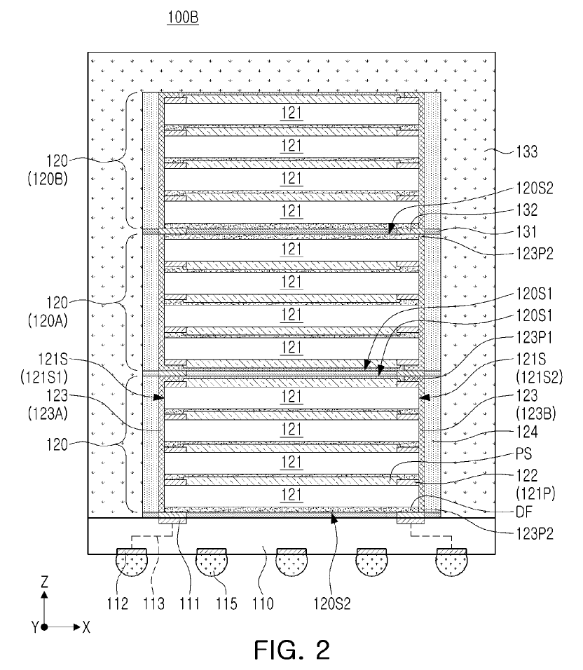

FIG. 2 is a longitudinal cross-sectional view of a semiconductor package 100B according to an example embodiment.

Referring to FIG. 2, the semiconductor package 100B according to an example embodiment may have features the same as, or similar to, those described with reference to one or more example embodiments in FIGS. 1A and 1B, except for a stacking direction of chip modules 120. At least one of the chip modules 120 may be disposed such that a first terminal portion 123P1 and a second terminal portion 123P2 of at least one of the chip modules 120 are oriented in a direction, different from that of a first terminal portion 123P1 and a second terminal portion 123P2 of another chip module 120. For example, the chip modules 120 may include at least one first chip module 120A, stacked such that the first surface 120S1 is oriented toward a substrate 110, and at least one second chip module 120B, stacked such that the second surface 120S2 is oriented toward the substrate 110. As described above, the chip modules 120 may form an electrical connection in a stacking direction (Z-direction) thereof, regardless of an arrangement direction of the first terminal portion 123P1 and the second terminal portion 123P2.

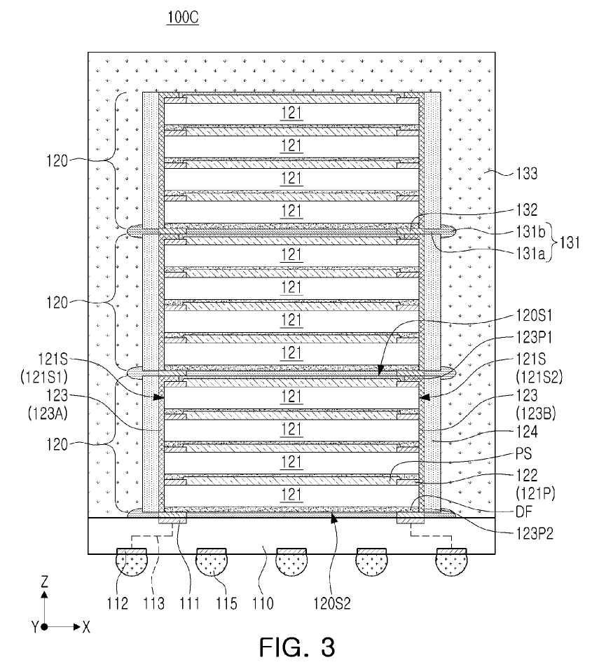

FIG. 3 is a longitudinal cross-sectional view of a semiconductor package 100C according to an example embodiment.

Referring to FIG. 3, the semiconductor package 100C according to an example embodiment may have features the same as, or similar to, those described with reference to FIGS. 1A, 1B and 2, except for a form of an attachment member 131. The attachment member 131 may include a first portion 131a filling the inside of peripheries of the chip modules 120, and a second portion 131b protruding toward the outside of the peripheries of the chip modules 120. For example, the attachment member 131 may comprise a synthetic resin, for example, an epoxy resin, a phenolic resin, a melamine resin, a polyester resin, a silicone resin, a urethane resin, a polyimide resin, an acrylic resin, or the like. The second portion 131b of the attachment member 131 may be a fillet formed during a stacking process of the chip modules 120.

FIG. 4 is a longitudinal cross-sectional view of a semiconductor package 100D according to an example embodiment.

Referring to FIG. 4, the semiconductor package 100D according to an example embodiment may have features the same as, or similar to, those described with reference to FIGS. 1A, 1B, 2 and 3, except for a type of an attachment member 131. The attachment member 131 may include an ACF. The attachment member 131 may include conductive particles CB dispersed in a film portion. The film portion may include, for example, at least one of an epoxy resin, polyurethane, an acrylic resin, polyethylene, a silicone polymer, a styrene butadiene block copolymer, or a styrene-ethylene-propylene-styrene block copolymer. The conductive particles CB may have a form in which a conductive material is coated on a surface of a core particle. The core particle may be a plastic ball, but one or more example embodiments are not limited thereto, and the core particle may be a conductive particle such as a carbon fiber or a metal ball. The conductive material, coated on the surface of the core particle, may include, for example, a metal material such as gold (Au), silver (Ag), nickel (Ni), or lead (Pd). In one or more example embodiments, a surface of the conductive material, that is, outermost portions of the conductive particles CB may be coated with an insulating skin layer. Accordingly, electrical conductivity may be exhibited in a compression direction (for example, a Z-direction) due to at least some conductive particles CB having a skin layer destroyed by high-temperature compression.

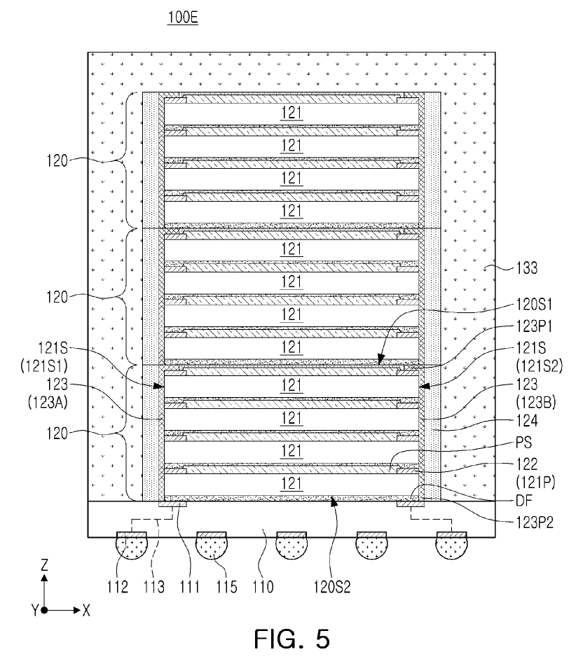

FIG. 5 is a longitudinal cross-sectional view of a semiconductor package 100E according to an example embodiment.

Referring to FIG. 5, the semiconductor package 100E according to an example embodiment may have features the same as, or similar to, those described with reference to FIGS. 1A, 1B, 2, 3 and 4, except for a connection structure of the chip modules 120. The chip modules 120 may be directly bonded and coupled to each other without a conductive member (for example, a solder ball, a metal pillar, or the like). The first terminal portion 123P1 and the second terminal portion 123P2 of each of the chip modules 120 may be in direct contact with and coupled to a vertically adjacent one among a bonding pad 111, a first terminal portion 123P1 and a second terminal portion 123P2 due to metal-to-metal bonding. The first terminal portion 123P1 and the second terminal portion 123P2 may include at least one of a material capable of forming metal-to-metal bonding, for example, copper (Cu), nickel (Ni), gold (Au), silver (Ag), titanium (Ti), and tantalum (Ta).

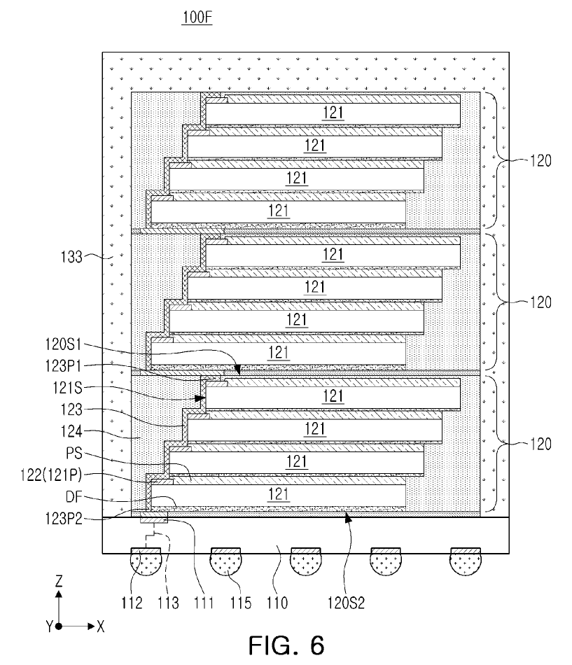

FIG. 6 is a longitudinal cross-sectional view of a semiconductor package 100F according to an example embodiment.

Referring to FIG. 6, the semiconductor package 100F according to an example embodiment may have features the same as, or similar to, those described with reference to FIGS. 1A, 1B, 2, 3, 4 and 5, except for a structure in which a plurality of semiconductor chips 121 are stacked. The plurality of semiconductor chips 121 may be stacked such that at least a portion of connection patterns 122 are exposed in a vertical direction (Z-direction). For example, the plurality of semiconductor chips 121 may be offset in a horizontal direction (for example, an X-direction) in which the connection patterns 122 are exposed. Even in this case, the connection patterns 122 may have ends aligned with side surfaces 121S of the semiconductor chips 121, and an interconnection pattern 123 may be in contact with the ends of the connection patterns 122, thereby minimizing a connection distance between the connection patterns 122.

FIG. 7 is a longitudinal cross-sectional view of a semiconductor package 100G according to an example embodiment.

Referring to FIG. 7, the semiconductor package 100G according to an example embodiment may have features the same as, or similar to, those described with reference to FIGS. 1A, 1B, 2, 3, 4, 5 and 6, except that a plurality of semiconductor chips 121 include a connection pad 121P, which is distinguished from a connection pattern 122. Each of the plurality of semiconductor chips 121 may further include a connection pad 121P spaced apart from one side surface 121S thereof. The connection pad 121P may be, for example, an aluminum (Al) pad, but one or more example embodiments are not limited thereto. The connection pattern 122 may pass through a passivation layer PS to be connected to the connection pad 121P. The connection pattern 122 may extend to the one side surface 121S of the semiconductor chip 121 along an upper surface of the passivation layer PS. At least one end of the connection pattern 122 may be aligned with the one side surface 121S of the semiconductor chip 121. The connection pattern 122 may be in contact with the interconnection pattern 123, on the one side surface 121S of the semiconductor chip 121.

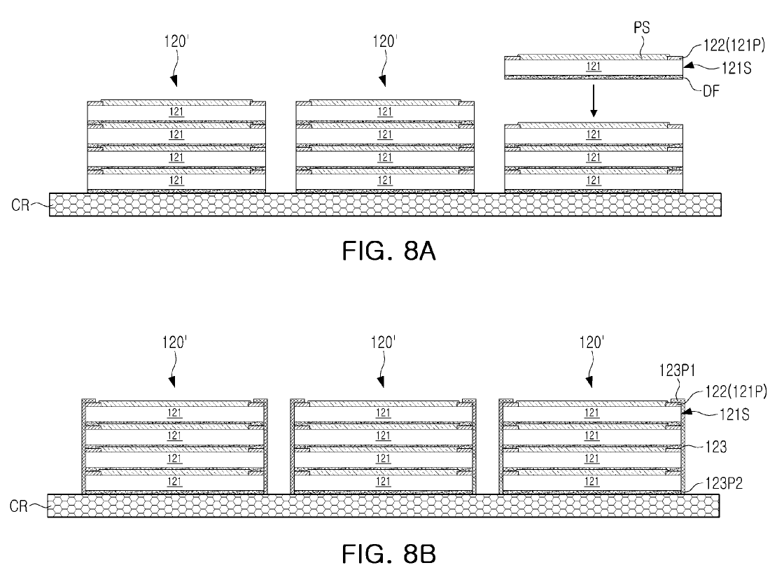

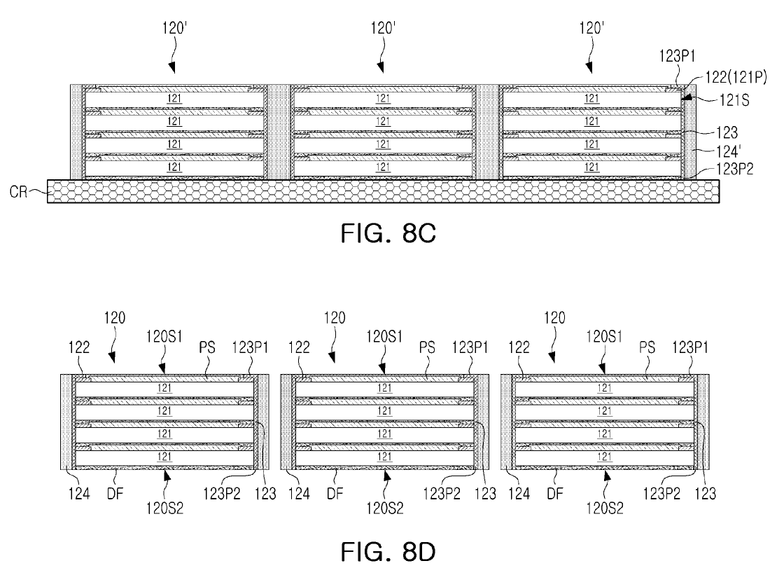

FIGS. 8A, 8B, 8C and 8D are diagrams illustrating a process of manufacturing a chip module according to an example embodiment.

Referring to FIG. 8A, chip stacks 120’ may be formed on a carrier CR. A release layer for separating the chip stacks 120’ from each other may be formed on an upper surface of the carrier CR. The chip stacks 120’ may include two or more semiconductor chips 121. The semiconductor chips 121 may be stacked such that side surfaces 121S are aligned in a vertical direction. An adhesive layer DF may be disposed on lower surfaces of the semiconductor chips 121. A connection pattern 122 of the semiconductor chip 121 may be buried in the adhesive layer DF disposed thereon. The side surface 121S of the semiconductor chip 121 and an end of the connection pattern 122 aligned therewith may be understood as a cut surface formed during a wafer dicing process. That is, the connection pattern 122 or the connection pad 121P may overlap a scribe lane of a semiconductor wafer, and may be coplanar with the one side surface 121S of the semiconductor chip 121 after a wafer is cut.

Referring to FIG. 8B, the interconnection pattern 123 may be formed on at least one side surface of each of the chip stacks 120’. For example, the interconnection pattern 123 may be formed by coating conductive ink including a metal such as aluminum (Al), silver (Ag), or the like. The conductive ink may be coated in the form of a pattern designed using a dispensing process or a printing process. In one or more example embodiments, the interconnection pattern 123 may be cured in the present operation or in a subsequent operation (FIG. 8C).

Referring to FIG. 8C, an encapsulation material layer 124’, covering the chip stacks 120’, may be formed. The encapsulation material layer 124’ may be formed using a transfer molding process and/or a compression molding process. For example, the encapsulation material layer 124’ may include an EMC. The encapsulation material layer 124’ may expose at least a portion of a first terminal portion 123P1. The encapsulation material layer 124’ may be formed to be coplanar with an upper surface of the first terminal portion 123P1.

Referring to FIG. 8D, the chip modules 120 may be separated from each other by cutting the encapsulation material layer 124’. After the carrier CR is removed, the chip modules 120 may have a first surface 120S1 and a second surface 120S2 opposite to each other. A plurality of semiconductor chips 121 may be connected to each other by the interconnection pattern 123. The plurality of semiconductor chips 121 may include a non-volatile memory chip and/or a volatile memory chip. The interconnection pattern 123 may connect the connection patterns 122 of the plurality of semiconductor chips 121 to each other. The interconnection pattern 123 may extend in a stacking direction (Z-direction) of the semiconductor chips 121 along the one side surfaces 121S of the plurality of semiconductor chips 121. The interconnection pattern 123 may be in contact with ends of the connection patterns 122 aligned with one side 121S of the semiconductor chips 121. The interconnection pattern 123 may provide a first terminal portion 123P1 on the first surface 120S1, and a second terminal portion 123P2 on the second surface 120S2. The encapsulant 124 may surround the side surfaces 121S of the plurality of semiconductor chips 121, and may expose at least a portion of each of the first terminal portion 123P1 and the second terminal portion 123P2.

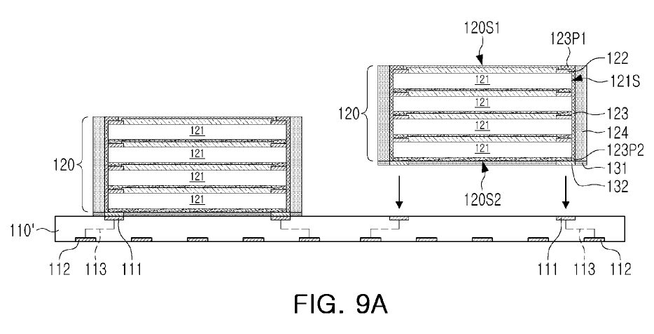

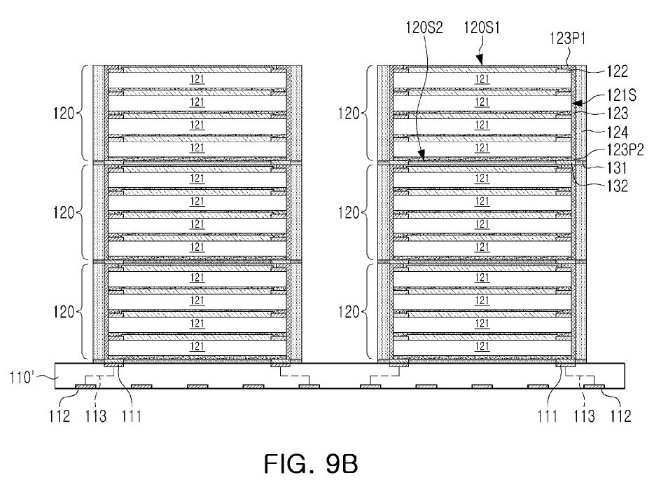

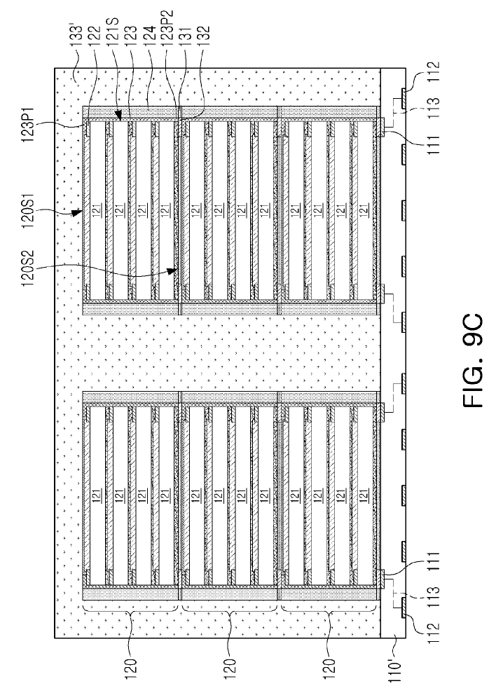

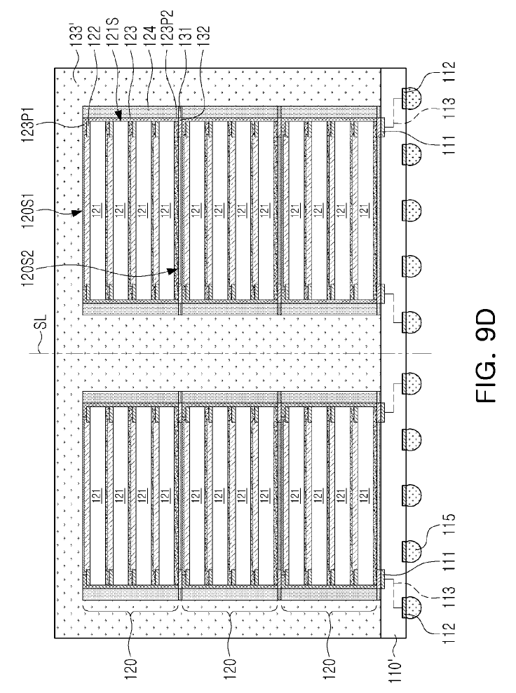

FIGS. 9A, 9B, 9C and 9D are diagrams illustrating a process of manufacturing a semiconductor package 100A according to an example embodiment.

Referring to FIG. 9A, a chip module 120 may be disposed on a strip substrate 110’. The chip module 120 may be disposed such that a first surface 120S1 or a second surface 120S2 is oriented toward a strip substrate 110’. An attachment member 131 and a conductive member 132 may be formed on the first surface 120S1 or the second surface 120S2 of the chip module 120. The conductive member 132 may be a pad or bump structure formed on a first terminal portion 123P1 or a second terminal portion 123P2 using a plating process, a dispensing process, or the like. The attachment member 131 may be an NCF, but one or more example embodiments are not limited thereto.

Referring to FIG. 9B, chip modules 120 may be stacked on the strip substrate 110’. The chip modules 120 may be stacked such that a first surface 120S1 or a second surface 120S2 is oriented toward the strip substrate 110’. An arrangement direction of the chip modules 120 is not limited. The chip modules 120 may be electrically connected to at least one chip module 120 adjacent thereto in a stacking direction through at least one first terminal portion 123P1 and at least one second terminal portion 123P2. According to an example embodiment, an electrical connection between the first terminal portion 123P1 and the second terminal portion 123P2 may be formed by an attachment member 131 and a conductive member 132. The attachment members 131 may be disposed between the chip modules 120. The attachment members 131 may attach and fix the chip modules 120 and electrically insulate the conductive members 132 from each other. The attachment members 131 may be cured in a thermal atmosphere. The conductive members 132 may be disposed in the attachment members 131. The conductive members 132 may electrically connect vertically adjacent ones among the bonding pad 111, the first terminal portion 123P1, or the second terminal portion 123P2, adjacent to each other in the stacking direction. In one or more example embodiments, the conductive members 132 may be in contact with only one of two components corresponding to each other in the stacking direction (for example, the example embodiment of FIG. 4).

Referring to FIG. 9C, a molding material layer 133’ may be formed. The molding material layer 133’ may be formed using a transfer molding process and/or a compression molding process. The molding material layer 133’ may surround side surfaces of the chip modules 120. The molding material layer 133’ may be formed to cover a terminal portion (for example, the first terminal portion 123P1) exposed to an upper surface of the uppermost chip module 120.

Referring to FIG. 9D, connection bumps 115 may be formed after the molding material layer 133’ is cured. Thereafter, the molding material layer 133’ and the strip substrate 11’ may be cut along a sawing line SL, such that semiconductor packages may be separated from each other.

According to example embodiments of the present disclosure, a chip module including terminal portions disposed in a stacking direction of a plurality of semiconductor chips may be introduced, and may thereby provide a high-performance and reduced-size semiconductor package and a method of manufacturing the same.

While one or more example embodiments have been particularly shown and described above, it will be apparent to those skilled in the art that modifications and variations in form and details may be made therein without departing from the spirit and scope of the following claims.

What is claimed is:

1. A semiconductor package comprising:
a substrate comprising a bonding pad;
chip modules, each of the chip modules comprising a first surface and a second surface opposite to the first surface, the chip modules being stacked in a vertical direction, one of the first surface or the second surface facing the substrate; and
a mold covering the chip modules,
wherein each of the chip modules comprises:
a plurality of semiconductor chips each comprising a connection pattern, the connection pattern comprising an end aligned with at least one side surface of each of the plurality of semiconductor chips;
an interconnection pattern contacting the end of the connection pattern of each of the plurality of semiconductor chips, the interconnection pattern comprising a first terminal portion on the first surface and a second terminal portion on the second surface; and
an encapsulant covering at least a portion of each of the plurality of semiconductor chips and covering the interconnection pattern, and
wherein at least one of the first terminal portion or the second terminal portion is electrically connected to a vertically adjacent one among: the bonding pad, the first terminal portion of a vertically adjacent one of the chip modules, and the second terminal portion of the vertically adjacent one of the chip modules.

2. The semiconductor package of claim 1, wherein the end of the connection pattern is coplanar with the at least one side surface of each of the plurality of semiconductor chips.

3. The semiconductor package of claim 1, wherein the plurality of semiconductor chips comprises:
first connection patterns adjacent to first side surfaces of the semiconductor chips; and
second connection patterns adjacent to second side surfaces of the semiconductor chips, and
wherein the interconnection pattern comprises:
a first interconnection pattern connecting the first connection patterns to each other; and
a second interconnection pattern connecting the second connection patterns to each other.

4. The semiconductor package of claim 1, wherein a portion of the first terminal portion is coplanar with the first surface, and
wherein a portion of the second terminal portion is coplanar with the second surface.

5. The semiconductor package of claim 1, wherein the encapsulant defines the first surface of the chip module, on a semiconductor chip most adjacent to the first terminal portion, among the plurality of semiconductor chips.

6. The semiconductor package of claim 1, wherein the encapsulant covers side surfaces of the plurality of semiconductor chips.

7. The semiconductor package of claim 1, wherein each of the plurality of semiconductor chips further comprises a passivation layer covering at least a portion of the connection pattern.

8. The semiconductor package of claim 1, wherein each of the chip modules further comprises adhesive layers respectively disposed on one surface of each of the plurality of semiconductor chips that is opposite to the connection pattern.

9. The semiconductor package of claim 8, wherein one of the adhesive layers, most adjacent to the second terminal portion, defines the second surface of each of the chip modules.

10. The semiconductor package of claim 1, further comprising:
attachment members between the chip modules;
an attachment member between one of the chip modules and the substrate; and
conductive members in the attachment members, each of the conductive members electrically connecting vertically adjacent ones among: the bonding pad, the first terminal portion, or the second terminal portion.

11. The semiconductor package of claim 10, wherein the attachment members comprise one of a non-conductive film (NCF) or an anisotropic conductive film (ACF), and
wherein the conductive members directly contact at least a vertically corresponding one among: the bonding pad, the first terminal portion, or the second terminal portion.

12. The semiconductor package of claim 10, wherein each of the attachment members comprises:
a first portion filling an inside of peripheries of two of the chip modules; and
a second portion protruding toward an outside of the peripheries of the two of the chip modules.

13. The semiconductor package of claim 1, wherein the chip modules comprise:
at least one first chip module comprising the first surface facing the substrate; and
at least one second chip module comprising the second surface facing the substrate.

14. The semiconductor package of claim 1, wherein the at least one of first terminal portion or the second terminal portion directly contacts a vertically adjacent one among: the bonding pad, the first terminal portion, and the second terminal portion.

15. The semiconductor package of claim 1, wherein each of the plurality of semiconductor chips further comprises a connection pad spaced apart from the one side surface, and
wherein the connection pattern connects the connection pad to the interconnection pattern.

16. A semiconductor package comprising:
a substrate comprising a bonding pad;
chip modules, each of the chip modules comprising a first surface and a second surface opposite to the first surface, the chip modules being stacked in a vertical direction, such that the first surface or second surface faces the substrate; and
a mold covering the chip modules,
wherein each of the chip modules comprises:
a plurality of semiconductor chips each comprising a connection pattern;
an interconnection pattern connecting the connection patterns of the plurality of semiconductor chips to each other, the interconnection pattern comprises a first terminal portion on the first surface and a second terminal portion on the second surface; and
an encapsulant covering at least a portion of each of the plurality of semiconductor chips and the interconnection pattern,
wherein at least one of first terminal portion or the second terminal portion is electrically connected to a vertically adjacent one among: the bonding pad, the first terminal portion of a vertically adjacent one of the chip modules, and the second terminal portion of the vertically adjacent one of the chip modules.

17. The semiconductor package of claim 16, wherein the interconnection pattern contacts an end of the connection pattern of the plurality of semiconductor chips, and
wherein the connection pattern is adjacent to one side surface of the respective one of the plurality of semiconductor chips.

18. The semiconductor package of claim 17, wherein the one side surfaces of the plurality of semiconductor chips are aligned in the vertical direction, and
wherein the interconnection pattern extends along the one side surfaces of the plurality of semiconductor chips.

19. The semiconductor package of claim 16, wherein the first terminal portion is contacts the first surface, and
wherein the second terminal portion contacts the second surface.

20. A semiconductor package comprising:
a substrate;
chip modules, each of the chip modules comprising a first surface and a second surface opposite to the first surface, the chip modules being stacked such that the first surface or the second surface faces the substrate; and
a mold covering the chip modules,
wherein each of the chip modules comprises:
a plurality of semiconductor chips each comprising a connection pattern;
an interconnection pattern extending in a stacking direction of the plurality of semiconductor chips and connected to the connection pattern of each of the plurality of semiconductor chips, the interconnection pattern comprising a first terminal portion on the first surface and a second terminal portion on the second surface; and
an encapsulant covering at least a portion of each of the plurality of semiconductor chips and covering the interconnection pattern, and
wherein each of the chip modules is electrically connected to a vertically adjacent one among the chip modules, through at least one of the first terminal portion or the second terminal portion.
